(19) United States
(12) Patent Application Publication
(10) Pub. No.: US 2012/0092029 A1
(43) Pub. Date: Apr. 19, 2012

(54) SENSOR ARRANGEMENT FOR CONTACTLESS DETERMINATION OF THE INSTANTANEOUS ANGULAR POSITION OF A SHAFT

(75) Inventor: Henning PRECHT, Petershagen (DE)

(73) Assignee: ABB Technology AG, Zurich (CH)

(21) Appl. No.: 13/217,751

(22) Filed: Aug. 25, 2011

(30) Foreign Application Priority Data
Aug. 25, 2010 (DE) 202010011758.5

(51) Int. Cl. G01R 27/26

(52) U.S. Cl. 324/660

(57) ABSTRACT

An exemplary sensor arrangement is disclosed for contactless determination of the instantaneous angular position of a shaft which has a transmitter, which is arranged thereon such that they rotate together and interacts with at least one pick-up, which is installed in a fixed position with respect thereto, for determining the angular position of the shaft. The fixed-position pick-up is formed by a first and a second circular disk, which are aligned plane-parallel with respect to one another and each have a central hole for guiding the shaft. The first disk is subdivided into four equal circular segments which are in the form of mutually isolated electrodes. The second disk is in the form of an opposing electrode with respect to the first disk. The transmitter is arranged as a solid dielectric, which is in the form of a disk, between the two disks and essentially has the form of a semicircle which is rigidly connected to the shaft.

This application claims priority under 35 U.S.C. §119 to German Patent Application No. 202010011758.5 filed in Germany on Aug. 25, 2010, the entire content of which is hereby incorporated by reference in its entirety.

### FIELD

The present disclosure encompasses electropneumatic or purely electrical position regulator units for actuating or control drives wherein, for example, a contactless measurement can be used to measure an angular position of a shaft to avoid wear to parts of the sensor arrangement which move relative to one another.

### BACKGROUND INFORMATION

Sensor arrangements are known for contactless determination of the instantaneous angular position of a shaft which has a transmitter, which is arranged thereon to rotate together with the shaft and which interacts with at least one pick-up, which is installed in a fixed position with respect thereto, for determining the angular position of the shaft.

In order to detect the angular position of a shaft contactlessly, that is to say without having to use any mechanical tapping, according to known prior art, a permanent magnet is fitted to the end face of the shaft and the direction of the magnetic field is determined; according to another known technical solution, a magnet ring having a plurality of magnet segments is attached along the circumference of the shaft, with the position within a magnet segment and the transition from one magnet segment to the next being determined and then being counted incrementally in order to achieve a 360° measurement range.

DE 44 15 686 A1 discloses a different technical solution for contactless determination of the instantaneous angular position of a shaft. In this case, the shaft is mounted such that it cannot only be moved axially but can also be rotated, and can assume defined axial positions and a defined angular position.

A position sensor is arranged parallel to the shaft and interacts with a permanent magnet which is attached to the shaft. The specific permanent magnet is in this case attached to the circumference of the shaft such that its longitudinal direction runs along a helical line such that both the axial movement of the shaft and its rotation result in different positions of that part of the permanent magnet which acts as the position sensor.

DE 42 39 635 A1 discloses a method for position detection of the valve rod movement of electropneumatic position regulators, in which an RF oscillation is excited within an LC resonant circuit in an inductively operating sensor in order to produce a radio-frequency electromagnetic alternating field, which is damped as a function of the position via an electrically conductive body which moves with the valve rod, and in which the oscillator signal is demodulated and is supplied without amplification to a microcomputer in order to evaluate the position-dependent oscillation amplitude damping. This method can allow for contactless position measurement, but the hardware complexity for carrying out the method is quite high and the measurement accuracy has been found to be inadequate, particularly in the event of vibration during harsh installation operation.

Furthermore, it is already known from DE 42 39 635 A1 for potentiometers, capacitive sensors and differential transformers, which are operated via a lever tap on a valve rod, to be used for position measurement of valve rods. However, known potentiometers are, for example, subject to wear, particularly when they are used in the area of severe mechanical vibration or shaking. This wear makes itself evident by increasing abrasion at the operating point of the potentiometer. The use of rotating capacitors can be very expensive, since complex protection measures have been taken in this case against moisture and, furthermore, very precise mechanical bearings are used. The use of differential transformers can involve an expensive mechanical bearing, since lateral movements of the magnet in the coil are to be suppressed. The electronics which are correspondingly used for supply purposes are also expensive and have a relatively high power consumption. Furthermore, attention should be paid to correct installation of the pick-ups, whose rotation angles are limited.

Known rotation angle sensors can consume high power. Furthermore, the trigonometric algorithms can place stringent specifications on the mechanical tolerances and the electrical tolerances of the sensor arrangement, in terms of type scatter, temperature drift and the like. In consequence, the measured-value resolution for only one permanent magnet can be reduced to a maximum of 14 bits.

### SUMMARY

A sensor arrangement is disclosed comprising: a transmitter for arrangement on a rotatable shaft; and at least one pick-up for installation at a fixed position with respect to the transmitter, for determining an angular position of the shaft, wherein: the fixed-position pick-up contains a first and a second circular disk, which disks are aligned plane-parallel with respect to one another and each have a central hole for guiding the shaft; the first disk is subdivided into four equal circular segments which are mutually isolated electrodes; the second disk is an opposing electrode with respect to the first disk; and the transmitter is arranged between the two disks as a solid, essentially semi-circular dielectric formed as a disk for rigid connection to the shaft.

### BRIEF DESCRIPTION OF THE DRAWINGS

Exemplary embodiments disclosed herein will be explained in more detail below with reference to one exemplary embodiment. In the drawings:

FIG. 1 shows an outline illustration of an exemplary sensor arrangement for contactless determination of the instantaneous angular position of a shaft;

FIG. 2 shows a normalized characteristic profile of each capacitance in the exemplary sensor arrangement; and

FIG. 3 shows a normalized characteristic profile of the exemplary sensor arrangement with a switched-capacitor sigma-delta converter.

### DETAILED DESCRIPTION

A sensor arrangement is disclosed for contactless determination of the instantaneous angular position of a shaft, which can produce an accurate measurement result while using little energy and few sensor components.

Exemplary embodiments are based on a sensor arrangement containing (e.g., consisting of) a transmitter, which is arranged on a shaft such that they rotate together, and at least one pick-up which is installed in a fixed position with respect to the transmitter, for determining the angular position of the shaft.

According to an exemplary embodiment, the fixed-position pick-up can be formed by a first and a second circular disk, which disks are aligned plane-parallel with respect to one another and each have a central hole for guiding the shaft. The first disk is subdivided into four equal circular segments which are in the form of mutually isolated electrodes. The second disk is in the form of an opposing electrode with respect to the first disk. The transmitter is arranged as a solid dielectric, which is in the form of a disk, between the two disks and essentially has the form of a semicircle which is rigidly connected to the shaft.

Each electrode on the first disk together with the opposing electrode on the second disk in each case forms a capacitor, whose capacitance is dependent on the degree of penetration of the intermediate space by the dielectric between the respective segment of the first disk and of the second disk

During desired use, the shaft rotates in the holes in the two disks, with the dielectric also being moved between the two disks and covering the mutually isolated electrodes as a function of the position. In this case, at least two electrodes on the first disk are all covered by the dielectric, and at least one electrode is free. The position of the shaft is calculated from the capacitances of the four capacitors.

Exemplary advantages of an exemplary sensor arrangement as disclosed herein are its mechanical robustness and the low level of electrical disturbance influence of the measurement mechanism.

According to a further feature, the four capacitors can be connected to a switched-capacitor sigma-delta converter for digitizing the capacitance values. With this type of converter, two measured values can be advantageously digitized in order to determine the position of the shaft. This results in a combination of a difference capacitance, which is constant over 90°, and a difference capacitance, which varies linearly with the rotation angle, in each quadrant.

A further exemplary advantage can in this case be seen in the highly energy-saving and high-accuracy analog-digital conversion.

Furthermore, exemplary sensor arrangements disclosed herein can have little dependency on temperature because the charge on each capacitor with a partially superimposed dielectric and a capacitance value between the capacitance with air insulation and the capacitance when completely covered by the dielectric is related to the charge on a capacitor with the capacitance value when completely covered by the dielectric.

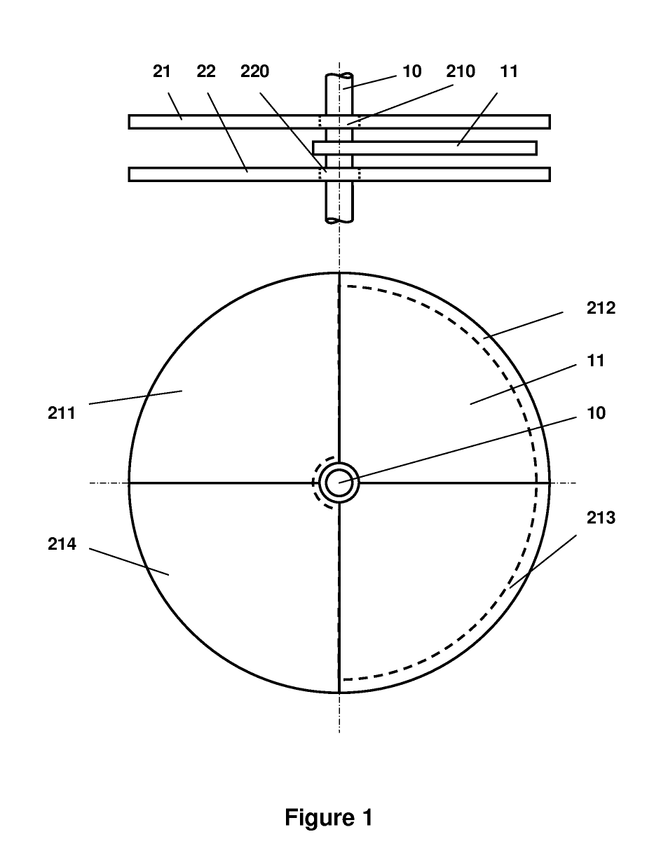

FIG. 1 shows an outline axial and radial view of a sensor arrangement for contactless determination of the instantaneous angular position of a shaft 10. A transmitter 11 is arranged on the shaft 10 such that they rotate together. The transmitter 11 is in the form of dielectric. The sensor arrangement furthermore has a pick-up, which is installed in a fixed position with respect to the transmitter 11.

The fixed-position pick-up includes (e.g., consists of) a first and a second circular disk 21 and 22, which are aligned plane-parallel with respect to one another and each have a central hole 210, 220 for guiding the shaft 10. The first disk 21 is subdivided into four equal circular segments 211, 212, 213 and 214, which are in the form of mutually isolated electrodes. The second disk 22 is in the form of an opposing electrode with respect to the first disk 21. The transmitter 11 is arranged as a solid dielectric, which is in the form of a disk, between the two disks 21 and 22 and essentially has the form of a semicircle which is rigidly connected to the shaft 10.

The sensor arrangement is therefore constructed in the form of a circular plate capacitor with a moving dielectric. In this case, the plate capacitor comprises four capacitors C1, C2, C3 and C4, which are distributed uniformly over its circumference.

Subject to the precondition that the plate area A is the same, the distance between the plates d is the same and the dielectric ∈ᵣ is the same, all the capacitors C1, C2, C3 and C4 initially have the same capacitance:

$${C}_{1 , 2 , 3 , 4} = {C}_{D} = {ɛ}_{0} \cdot {ɛ}_{r} \cdot \frac{A}{d} \qquad ( 1 )$$

The capacitance values of the capacitors C1, C2, C3 and C4 vary, depending on the position of the transmitter 11 and therefore of the respectively acting dielectric, between C_{L}, when there is only air between the plates, and ∈ᵣ≈1:

$${C}_{L} = {ɛ}_{0} \cdot \frac{A}{d} \qquad ( 2 )$$

and the capacitance value C_{D} based on formula 1 but with ∈ᵣ>1, when the plates of a capacitor completely cover the dielectric.

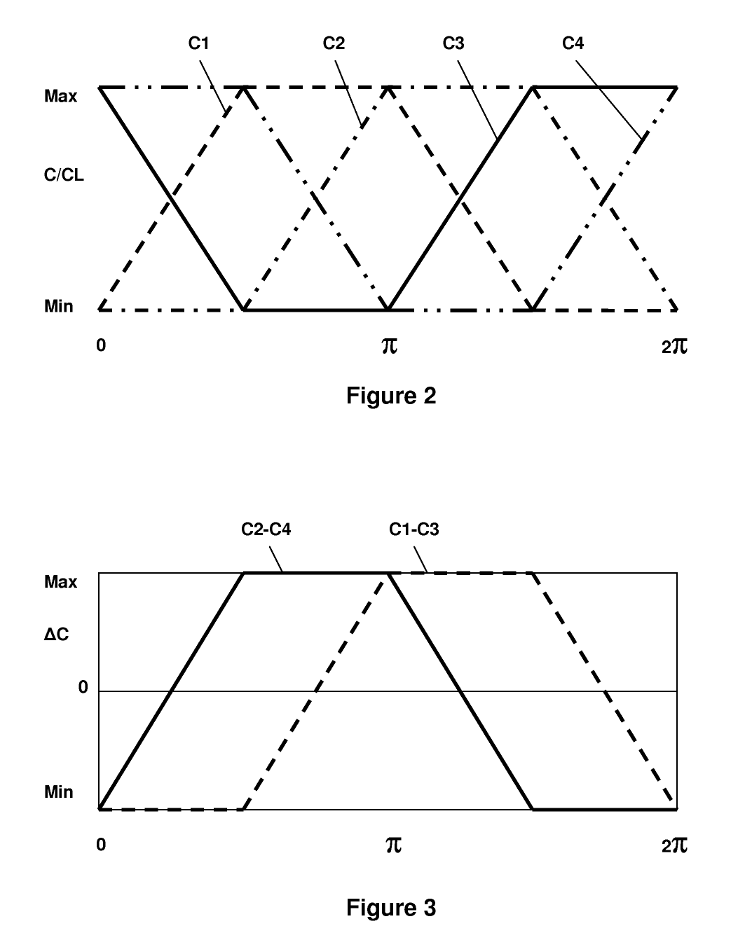

The capacitances of the individual capacitors C1, C2, C3 and C4 are plotted in a normalized form over one revolution of the shaft 10 in FIG. 2. The essentially (i.e., substantially) semicircular transmitter 11 in each case covers two adjacent circle segments 211, 212, 213 and 214 completely, or one of the circle segments 211, 212, 213 and 214 completely and the two immediately adjacent circle segments 211, 212, 213 or 214 in a complementary form over part of the area. In consequence, the rotation of the shaft 11 in each case produces an increase in the capacitance of the capacitor C1, C2, C3 and C4 in a circle segment 211, 212, 213 and 214 and, to the same extent, a reduction in the capacitance of the capacitor C3, C4, C1 or C2 of the respectively opposite circle segment 213, 214, 211 and 212.

In a further exemplary refinement, the four capacitors C1, C2, C3 and C4 are connected to a switched-capacitor sigma-delta converter, which is known per se, for digitizing the capacitance values. In this case, the difference between the capacitances of two associated capacitors C1, C2, C3 and C4 is in each case evaluated. In this case, it can be particularly advantageous to relate respective capacitors C1/C3 and C2/C4 in opposite circle segments 211/213 and 212/214.

FIG. 3 shows the normalized capacitance differences of capacitors C1/C3 and C2/C4 in respectively opposite circle segments 211/213 and 212/214 over one revolution of the shaft 10. In each quadrant, the capacitance difference of in each case one capacitor pair C1/C3 and C2/C4 varies, where the capacitance difference of the respective other capacitor pair C2/C4 and C1/C3 remains the same. The position of the shaft 10 is therefore determined significantly by means for performing (e.g., converter drive) switched-capacitor sigma-delta conversion by the capacitance difference of in each case one capacitor pair C1/C3 or C2/C4.

In one exemplary particular refinement, a so-called capacitance-to-digital converter, which is known per se, is provided for digitizing the capacitances of the capacitors C1/C3 and C2/C4. This type of converter belongs to the family of switched-capacitor sigma-delta converters mentioned above. However, the charge on the capacitors C1/C3 and C2/C4 to be measured can be particularly advantageously used directly in order to digitize the capacitor voltage. This can avoid the charging of the input capacitor that is normally used in switched-capacitor sigma-delta converters, whose charge reversal is lossy and can therefore lead to measurement errors.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE SYMBOLS

10 Shaft
11 Transmitter
21, 22 Disk
210, 220 Hole
211, 212, 213, 214 Circular segment
C1, C2, C3, C4 Capacitor

1. A sensor arrangement comprising:
a transmitter for arrangement on a rotatable shaft; and
at least one pick-up for installation at a fixed position with respect to the transmitter, for determining an angular position of the shaft, wherein:
the fixed-position pick-up contains a first and a second circular disk, which disks are aligned plane-parallel with respect to one another and each have a central hole for guiding the shaft;
the first disk is subdivided into four equal circular segments which are mutually isolated electrodes;
the second disk is an opposing electrode with respect to the first disk; and
the transmitter is arranged between the two disks as a solid, essentially semi-circular dielectric formed as a disk for rigid connection to the shaft.

2. The sensor arrangement as claimed in claim 1, wherein each electrode on the first disk together with the opposing electrode on the second disk in each case forms one of four capacitors, each of whose capacitance is dependent on a degree of penetration of an intermediate space by the dielectric between a respective circular segment of the first disk and the second disk.

3. The sensor arrangement as claimed in claim 2, wherein
the four capacitors are connected to a switched-capacitor sigma-delta converter for digitizing the capacitance values.
